(19) United States
(12) Patent Application Publication
(10) Pub. No.: US 2026/0346800 A1
(43) Pub. Date: Nov. 5, 2026

(54) WIRELESS POWER SUPPLY DEVICE FOR VEHICLE SEAT

(71) Applicant: AMOSENSE CO., LTD., Cheonan-si, Chungcheongnam-do (KR)

(72) Inventors: Cholhan KIM, Cheonan-si (KR); Wonsan NA, Cheonan-si (KR); Bohyeon HAN, Cheonan-si (KR)

(73) Assignee: AMOSENSE CO., LTD., Cheonan-si, Chungcheongnam-do (KR)

(21) Appl. No.: 19/108,023

(22) PCT Filed: Aug. 30, 2023
(86) PCT No.: PCT/KR2023/012839

§ 371 Date: Feb. 28, 2025

(30) Foreign Application Priority Data
Sep. 1, 2022 (KR) 10-2022-0110445

(51) Int. Cl. B60R 16/03; B60N 2/02; B60N 2/07; H02J 50/10; H02J 50/40; H02J 50/70; H05K 9/00

(52) U.S. Cl. CPC B60R 16/03; B60N 2/02258; B60N 2/07; H02J 50/10; H02J 50/402; H02J 50/70; H05K 9/0081

(57) ABSTRACT

Disclosed herein is a wireless power supply device for a vehicle seat which can wirelessly supply power to the vehicle seat. The wireless power supply device includes: rail frames each having a first opening formed to allow linear movement of a seat connector connected to the vehicle seat; a motor coupled to the seat connector and movably installed in each rail frame; a wireless power transmission board fixed inside the rail frame, and provided with transmission coils connected to a power source; and a wireless power reception board that faces the wireless power transmission board, is provided with a reception coil configured to receive power transmitted from the transmission coils, and is linearly movable in conjunction with the motor. The wireless power transmission board and the wireless power reception board are installed perpendicular to a bottom surface of the rail frame at positions spaced apart from the motor.

### TECHNICAL FIELD

The present disclosure relates to a wireless power supply device for a vehicle seat, and more specifically, to a wireless power supply device for a vehicle seat capable of wirelessly supplying power to the vehicle seat that moves along a movement path.

### BACKGROUND ART

Generally, vehicle seats move forward and backward along rails installed on a floor surface of a passenger compartment of a vehicle. Various devices requiring power, such as heating wires and motors, are mounted in such vehicle seats to provide various convenience functions such as memory seat functions, ventilation, and heating.

Existing vehicle seats are electrically connected to a power source of the vehicle through a power cable, and receive power through the power cable to supply power to various devices mounted inside the seat. Various devices mounted in the vehicle seat operate by the power supplied through the power cable, and provide various convenience functions such as memory seat functions, ventilation, and heating to an occupant of the vehicle.

However, such existing vehicle seats have a structure in which the power source of the vehicle is directly electrically connected to various devices installed inside the seat through multiple power cables. Therefore, during movement of the vehicle seat, interference and entanglement between the power cables may occur, which may result in a phenomenon where power is not properly supplied or transmitted.

Furthermore, as the wiring of the power cables becomes more complicated, the power cables may be exposed outside the vehicle seat during movement of the vehicle seat, thereby impairing the appearance. In addition, the exposed cables may become damaged, resulting in not only failure in operation of various devices installed inside the seat, but also failure in operation of the seat itself.

Moreover, during installation of the vehicle seat, the power source of the vehicle needs to be individually electrically connected to various devices installed in the seat through power cables, thereby causing a problem of reduced work efficiency.

To overcome various problems as described above, vehicle seats equipped with a wireless power supply device are recently under development, the wireless power supply device being configured to wirelessly receive power from the power source of the vehicle and supply the received power to various devices installed in the vehicle seat to operate various convenience functions.

However, a large amount of electromagnetic waves may be generated during a process of wirelessly supplying power to the vehicle seat through the wireless power supply device. The electromagnetic waves generated in the aforementioned manner may cause an increase in electromagnetic interference (EMI), which may result in damage to or malfunction of various electronic devices installed inside the vehicle.

Electronic devices installed inside the vehicle are essentially required to pass EMI tests. However, as described above, a large amount of electromagnetic waves that may cause malfunction of the electronic devices of the vehicle are generated during the process of wirelessly supplying power to the vehicle seat, making it difficult to pass stringent EMI certification for electronic components.

Accordingly, there is an urgent need for a method capable of minimizing electromagnetic waves generated from vehicle seats equipped with a wireless power supply device.

### SUMMARY OF INVENTION

### Technical Problem

The present disclosure has been devised to solve the above problem, and an object of the present disclosure is to provide a wireless power supply device for a vehicle seat, capable of minimizing electromagnetic waves generated during a process of wirelessly supplying power to the vehicle seat.

Another object of the present disclosure is to provide a wireless power supply device for a vehicle seat, capable of improving design flexibility of a bottom surface of a vehicle body where a rail frame is installed, by optimizing arrangement of a wireless power transmission and reception module in a confined internal space of the rail frame and minimizing an increase in cross-sectional area of the rail frame.

### Solution to Problem

To achieve the above object, a wireless power supply device for a vehicle seat according to an embodiment of the present disclosure may include: a pair of rail frames each having a first opening formed to allow linear movement of a seat connector connected to the vehicle seat; a motor coupled to the seat connector and linearly movably installed inside each of the pair of rail frames; a wireless power transmission board fixed inside the rail frame, and provided with a plurality of transmission coils connected to a power source inside a vehicle to wirelessly transmit power; and a wireless power reception board disposed at a position facing the wireless power transmission board, and provided with a reception coil configured to receive power wirelessly transmitted from the transmission coils, the wireless power reception board being configured to move linearly in conjunction with the motor. The wireless power transmission board and the wireless power reception board may be installed perpendicular to a bottom surface of the rail frame at positions spaced apart in a horizontal direction from the motor.

In an embodiment, a first shielding component may be installed at the first opening of the rail frame and configured to block electromagnetic waves generated during wireless power transmission from the wireless power transmission board to the wireless power reception board from being emitted outside through the first opening.

In an embodiment, the first shielding component may be formed by mixing an elastically deformable material with electromagnetic interference (EMI) powder having an electromagnetic wave shielding function.

In this case, the first shielding component may be formed of memory foam having elastic restoring force, and may include a pair of first shielding components installed on opposite sides facing each other in the first opening and configured to close the first opening by elastically coming into close contact with each other.

In addition, the first shielding component may be formed in a brush structure having elastic restoring force, and may include a pair of first shielding components installed on opposite sides facing each other in the first opening and configured to close the first opening.

Furthermore, the rail frame may include a first space in which the motor is disposed, and a second space partitioned from the first space by a partition wall, with the wireless power transmission board and the wireless power reception board disposed in the second space.

In an embodiment, the wireless power transmission board and the wireless power reception board may be installed in the second space and oriented perpendicular to the bottom surface of the rail frame.

Furthermore, a second opening may be formed in the partition wall to allow linear movement of a connection bracket that connects the wireless power reception board to the motor.

In an embodiment, a second shielding component may be installed at the second opening and configured to block electromagnetic waves generated during wireless power transmission from the wireless power transmission board to the wireless power reception board from being emitted to the first space through the second opening.

In this case, the second shielding component may be formed by mixing an elastically deformable material with electromagnetic interference (EMI) powder having an electromagnetic wave shielding function.

Furthermore, the second shielding component may be formed of memory foam having elastic restoring force, and may include a pair of second shielding components installed on opposite sides facing each other in the second opening and configured to close the second opening by elastically coming into close contact with each other.

In addition, the second shielding component may be formed in a brush structure having elastic restoring force, and may include a pair of second shielding components installed on opposite sides facing each other in the second opening and configured to close the second opening.

A wireless power supply device for a vehicle seat according to an embodiment of the present disclosure may include: a rail frame having an opening formed to allow linear movement of a seat connector connected to the vehicle seat; a motor coupled to the seat connector and linearly movably installed inside the rail frame; a wireless power transmission board fixed to one side inside the rail frame, and provided with a plurality of transmission coils connected to a power source inside a vehicle to wirelessly transmit power; and a wireless power reception board provided with a plurality of reception coils configured to receive power wirelessly transmitted from the transmission coils, the wireless power reception board being disposed at a position facing the wireless power transmission board and configured to move linearly in conjunction with the motor. The wireless power transmission board and the wireless power reception board may be installed below the motor at positions spaced apart from the motor, and may be oriented parallel to a bottom surface of the rail frame.

In an embodiment, the wireless power supply device may further include wheels disposed on opposite sides below the motor and configured to roll along the rail frame. The wireless power transmission board and the wireless power reception board may be installed in an inner space between the opposite wheels positioned below the motor, and may be oriented parallel to a bottom surface of the rail frame.

Furthermore, a shielding component may be installed at the opening of the rail frame and configured to block electromagnetic waves generated during wireless power transmission from the wireless power transmission board to the wireless power reception board from being emitted outside through the opening.

In this case, the shielding component may be formed by mixing an elastically deformable material with electromagnetic interference (EMI) powder having an electromagnetic wave shielding function.

Furthermore, the shielding component may be formed of memory foam having elastic restoring force, and may include a pair of shielding components installed on opposite sides facing each other in the opening and configured to close the opening by elastically coming into close contact with each other.

In addition, the first shielding component may be formed in a brush structure having elastic restoring force, and may include a pair of shielding components installed on opposite sides facing each other in the opening and configured to close the opening.

### Advantageous Effects of Invention

According to a wireless power supply device for a vehicle seat in accordance with the present disclosure having the above-described configuration, a motor is installed in a first space of a rail frame, and a wireless power transmission board and a wireless power reception board are installed perpendicular to a bottom surface of the rail frame in a second space partitioned from the first space by a partition wall, thereby providing a wireless power supply device utilizing side spaces inside the rail frame. Accordingly, a left and right width and a height of the rail frame can be reduced, thereby minimizing an increase in overall cross-sectional area of the rail frame. As a result, spatial utilization of a lower portion of a vehicle body where the rail frame is installed can be increased, thereby improving design flexibility for the lower portion of the vehicle body.

Furthermore, a shielding component having an electromagnetic wave shielding function is installed at an upper opening of the rail frame through which the seat connector passes, thereby effectively blocking electromagnetic waves generated during wireless power transmission and reception in a wireless power supply unit from being emitted to the outside through the upper opening. Accordingly, electromagnetic waves generated from the vehicle seat can be minimized.

Particularly, each shielding component is configured in the form of sponge, memory foam, or brush having an electromagnetic wave shielding function, and a pair of such shielding components are installed on opposite sides facing each other at the opening to close the opening by elastically coming into close contact with each other. Therefore, there is an advantage in that the shielding components can effectively block electromagnetic waves emitted through the opening without interfering with movement of the vehicle seat.

In addition, the present disclosure provides a dual shielding structure in which a second shielding component primarily blocks electromagnetic waves generated during wireless power transmission and reception from being emitted into the first space through a second opening, and a first shielding component secondarily blocks electromagnetic waves from being emitted to the outside through the first opening from the first space. Therefore, there is an advantage in that electromagnetic waves generated from the vehicle seat can be minimized, thereby significantly contributing to obtaining stringent electromagnetic interference (EMI) certification for vehicle electronic components.

Furthermore, in a design specification in which the vehicle seat is driven using a single rail frame, the wireless power transmission board and the wireless power reception board are installed below the motor at positions spaced apart from the motor by predetermined distances, and provided to be parallel to the bottom surface of the rail frame in an inner clearance space between opposite wheels moving along the rail frame. Accordingly, since the wireless power transmission board and the wireless power reception board can be installed by utilizing the clearance space between the opposite wheels located below the motor, there is no need to separately secure additional space for installation of the wireless power transmission board and the wireless power reception board inside the rail frame, and the horizontal width and vertical height of the cross-section of the rail frame can be minimized. Therefore, spatial utilization of the lower portion of the vehicle body where the rail frame is installed can be increased, thereby improving design flexibility for the lower portion of the vehicle body.

### BRIEF DESCRIPTION OF DRAWINGS

FIG. 1 is a side view illustrating a side profile of a vehicle seat equipped with a wireless power supply device according to an embodiment of the present disclosure.

FIG. 2 is a perspective view illustrating a pair of rail frame structures installed under a vehicle seat.

FIG. 3 is an enlarged view illustrating an enlargement of a first side rail frame shown in FIG. 2.

FIG. 4 is a perspective view illustrating a motor that is movably installed inside a rail frame.

FIG. 5 is a diagram illustrating an internal configuration of the rail frame according to an embodiment of the present disclosure.

FIG. 6 is a plan view illustrating a coil arrangement structure on wireless power transmission and reception boards installed inside the rail frame.

FIG. 7 is a block diagram illustrating a circuit configuration connected to respective coils of the wireless power transmission and reception boards.

FIG. 8 is a plan view illustrating a first opening space, in which a seat connector is located, being shielded by a first shielding component.

FIGS. 9 and 10 are sectional views illustrating shielding component installation structures according to other embodiments of the present disclosure.

FIG. 11 is a cross-sectional view illustrating an internal configuration and an electromagnetic wave shielding structure of a rail frame according to another embodiment of the present disclosure.

### DESCRIPTION OF EMBODIMENT

Hereinafter, embodiments of the present disclosure will be described in detail with reference to the attached drawings so that those skilled in the art can easily implement the present disclosure.

The present disclosure may be embodied in various different forms, and is not limited to the following embodiments. In addition, it should be noted that parts denoted by the same reference numerals throughout the detailed description indicate the same components.

Hereinafter, embodiments of a wireless power supply device for vehicle seats according to the present disclosure will be described in detail with reference to the accompanying drawings.

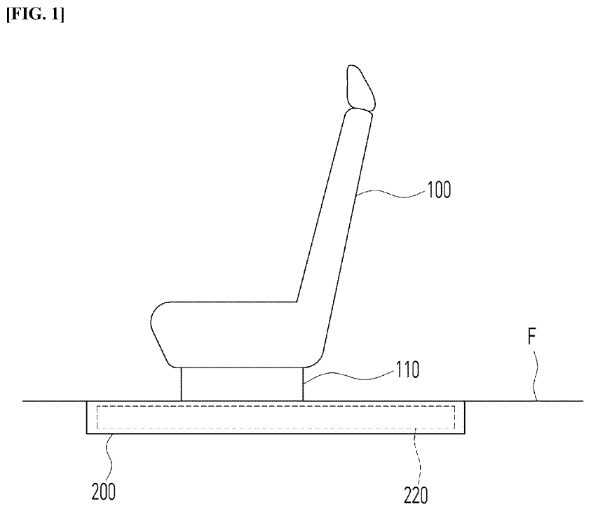

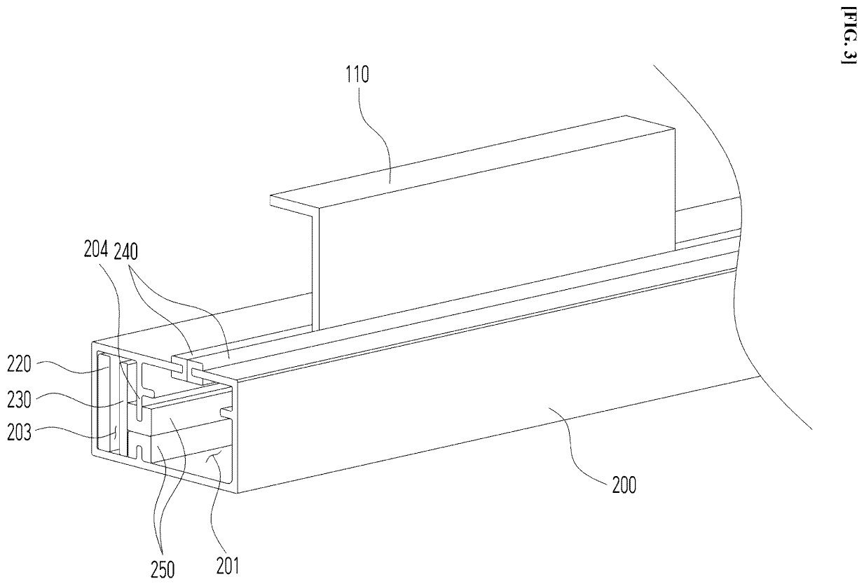

Referring to FIGS. 1 to 5, a wireless power supply device for vehicle seats according to the present disclosure includes: a pair of rail frames 200 each having a first opening 202 formed to allow linear movement of a seat connector 110 connected to a vehicle seat 100; a motor 210 coupled to the seat connector 110 and linearly movably installed inside each of the rail frames 200; a wireless power transmission board 220 fixed inside each of the rail frames 200 and connected to a power source inside the vehicle to wirelessly transmit power; and a wireless power reception board 230 disposed at a position facing the wireless power transmission board 220, the wireless power reception board 230 being configured to move linearly in conjunction with the motor 210 and to receive power wirelessly transmitted from the wireless power transmission board 220.

The pair of rail frames 200 are installed parallel to each other in a symmetrical arrangement on a floor surface F in a passenger compartment of the vehicle, thereby forming a movement path of the vehicle seat 100 and guiding forward and backward movement of the vehicle seat 100. In this case, the pair of rail frames 200 may be installed in an embedded form under the floor surface F of a vehicle body so as not to be exposed above the floor surface F in the passenger compartment of the vehicle.

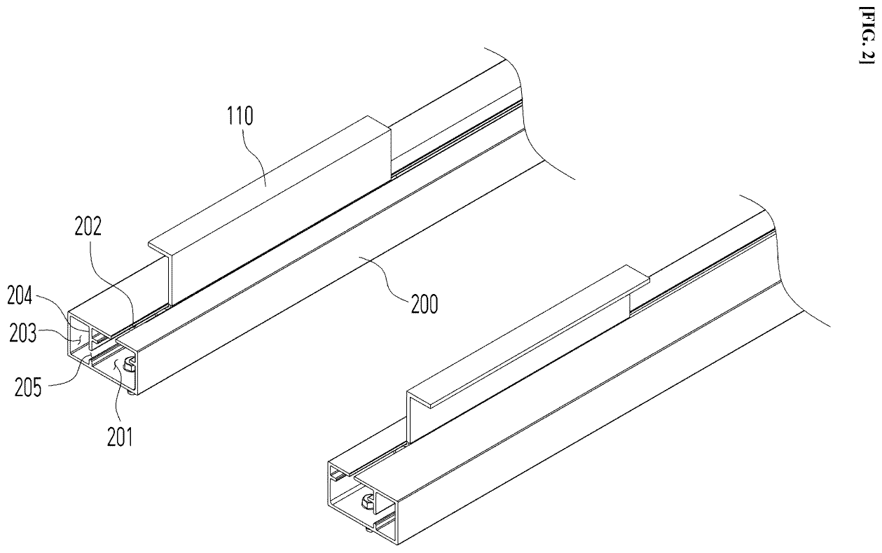

As illustrated in FIG. 2, the first opening 202 is formed in an upper surface of each of the rail frames 200, the first opening 202 being open in an upward and downward direction (vertical direction) to allow linear movement of the seat connector 110 coupled to the vehicle seat 100 along the rail frame 200. For example, FIG. 2 illustrates a state before first and second shielding components 240 and 250, which will be described later, are installed.

Interior of the rail frame 200 is sectioned into a first space 201, in which the motor 210 is installed, and a second space 203, which is partitioned from the first space 201 by a partition wall 204 and in which the wireless power transmission board 220 and the wireless power reception board 230 are installed.

The motor 210 is coupled to the vehicle seat 100 through the seat connector 110, and is installed to be movable linearly along a longitudinal direction of the rail frame 200 in the first space 201.

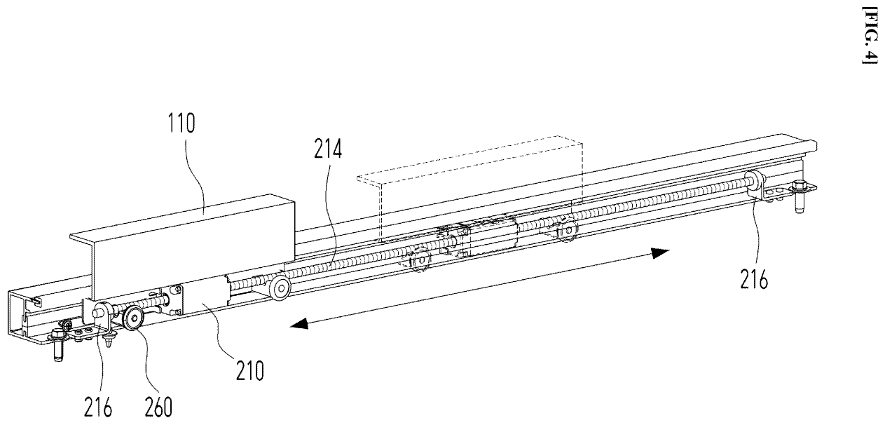

In other words, as shown in FIG. 4, the motor 210 is installed to be movable linearly in a forward or backward direction along a lead screw 214 fixed inside the first space 201 of the rail frame 200.

A pair mounting brackets 216, each of which is bent in an ‘L’-shape, are respectively fixed to front and rear end bottom surfaces 201a of first space 201. Opposite ends of lead screw 214 are fixed to bent ends of the respective mounting brackets 216.

The Lead screw 214 is disposed at a position spaced apart by a predetermined distance above from the bottom surface 201a of the first space 201 by the mounting brackets 216 each having an ‘L’-shape. The opposite ends of the lead screw 214 are unrotatably fixed to the mounting brackets 216.

The motor 210 is a hollow-type BLDC motor, and has a structure in which a stator (not shown) provided with a coil and a rotor (not shown) provided with a magnet are assembled with each other in a rectangular casing 212.

A screw hole (not shown) is formed at a center of the rotor of the motor 210, and the lead screw 214 is threaded into the screw hole. Accordingly, when the rotor of the motor 210 is driven, the rotor, which is threadedly engaged with the lead screw 214 that is in the fixed state, performs relative motion, thereby allowing the motor 210 to move linearly in the forward or backward direction along the lead screw 214.

One or more wheels 260 may be provided on left and right sides of the motor 210 to roll along the rail frame 200 during a process in which the motor 210 moves linearly along the lead screw 214.

Here, the wheels 260 are disposed at positions adjacent to left and right side surfaces of the motor 210, and move along the rail frame 200, thereby serving to support the motor 210 so that the motor 210 can reliably linearly move without rotating during the process in which the motor 210 moves along the lead screw 214.

The seat connector 110 connected to the vehicle seat 100 is coupled to the motor 210, and moves in the forward or backward direction along the first opening 202 of the rail frame 200 in conjunction with the motor 210 during the forward or backward movement of the motor 210.

In this case, a lower end of the seat connector 110 may be coupled in surface contact with multiple portions of an outer surface of the rectangular casing 212, which forms an outer periphery of the motor 210. For example, the lower end of the seat connector 110 may be coupled in surface contact with opposite side surfaces and front and rear surfaces of the outer casing 212 of the motor 210 in such a way that the seat connector 110 encloses the surfaces of the outer casing 212 of the motor 210 at multiple positions.

Accordingly, coupling force between the seat connector 110 and the motor 210 is firmly maintained, thereby providing a rigid structure capable of supporting a load transmitted from the vehicle seat 100 to the motor 210 through the seat connector 110.

In an embodiment, a wireless power supply unit configured to wirelessly supply power to the motor 210 and various devices installed in the seat 100 is installed inside the rail frame 200.

For example, the wireless power supply unit may be installed in the second space 203, which is a space separately provided on an inner side surface of the rail frame 200, so as to prevent damage caused by friction generated during the forward or backward movement of the vehicle seat 100.

The wireless power supply unit includes the wireless power transmission board 220 electrically connected to the power source inside the vehicle to wirelessly transmit power, and the wireless power reception board 230 configured to receive power wirelessly transmitted from the wireless power transmission board 220.

Here, the wireless power transmission board 220 and the wireless power reception board 230 may be disposed in the second space 203, which is spaced apart by a predetermined distance in a horizontal direction from the motor 210 installed in the first space 201, and may be installed perpendicular to the bottom surface 201a of the rail frame 200.

The wireless power transmission board 220 may be disposed in the second space 203 at a position relatively farther from the motor 210, and may be coupled to a side surface of rail frame 200 by a fastening unit such as a bolt.

The wireless power reception board 230 is disposed in parallel at a position facing the wireless power transmission board 220 in the second space 203, and is movable linearly in the second space 203 in conjunction with the motor 210.

In other words, the wireless power reception board 230 is provided in the second space 203 at a position relatively close to the motor 210, and is connected to the motor 210 through a connection bracket 215, thereby being movable linearly in the second space 203 along with the motor 210.

Here, a second opening 205 is formed in a portion of the partition wall 204 that horizontally partitions the first space 201 and the second space 203, the second opening 205 being open in a left and right direction (horizontal direction) to allow linear movement of the connection bracket 215, which connects the wireless power reception board 230 and the motor 210 (refer to FIG. 2).

The connection bracket 215 has a U-shaped bent cross-section and mechanically couples the motor 210 and the wireless power reception board 230. Various cables for supplying power from the wireless power reception board 230 to the motor 210 and the seat 100 pass through the region of the second opening 205 together with the connection bracket 215, and are connected to the motor 210 and various devices provided inside the seat 100.

Accordingly, the motor 210 receives power transmitted from the wireless power transmission board 220 to the wireless power reception board 230, and is driven to move along lead screw 214. The wireless power reception board 230, which is connected to the motor 210 through the connection bracket 215, also moves in the second space 203 in conjunction with the motor 210, and is capable of supplying power required for various devices installed in the seat 100.

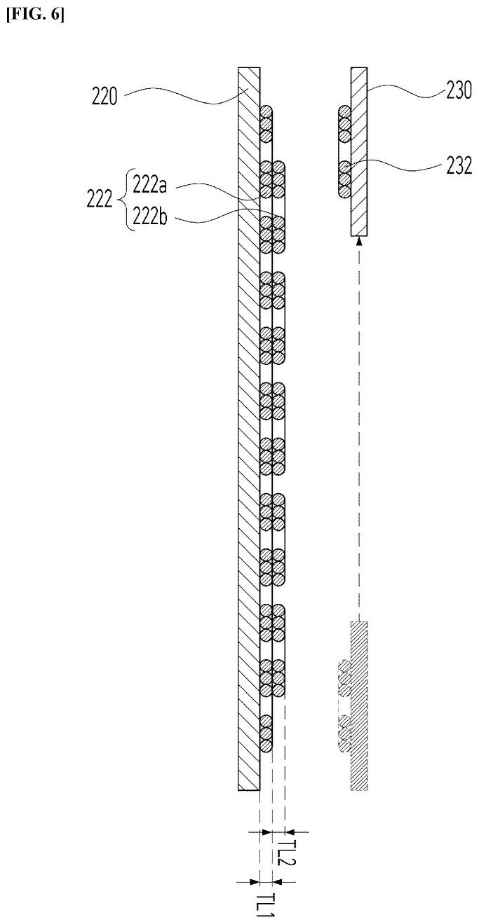

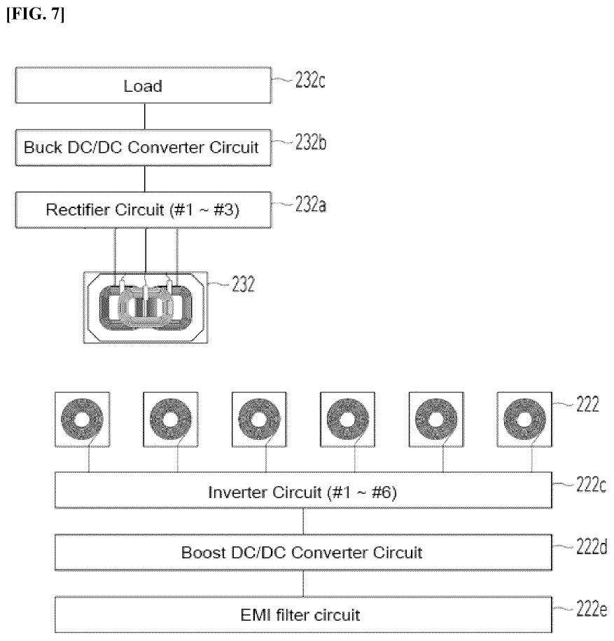

FIGS. 6 and 7 show an example of a coil arrangement structure in the wireless power transmission and reception boards 220 and 230, which form the wireless power supply unit, and an example of a circuit configuration connected to each coil of the wireless power transmission and reception boards 220 and 230.

The wireless power supply unit may perform wireless transmission of power (or signals) through the wireless power transmission board 220 and the wireless power reception board 230, thereby supplying power to the vehicle seat 100.

In other words, the wireless power supply unit may supply power required for various devices installed in the vehicle seat 100 through wireless power transmission between the wireless power reception board 230, which operates in conjunction with the motor 210, and the wireless power transmission board 220 fixed to the rail frame 200.

As described above, the wireless power supply unit wirelessly supplies power to the vehicle seat 100 through wireless power transmission, thereby preventing problems such as entanglement and damage of power cables and impairment of appearance, which may occur in existing power supply methods using wired power cables, and also solving problems such as reduced work efficiency and increased installation cost resulting from connection of the power cables.

As shown in FIG. 6, the wireless power transmission board 220 may be provided with a plurality of transmission coils 222, which are connected to the power source and a controller inside the vehicle and wirelessly transmit power and control signals. The wireless power reception board 230 may be provided with a plurality of reception coils 232, which receive power wirelessly transmitted from the transmission coils 222 of the wireless power transmission board 220.

The plurality of transmission coils 222 provided on the wireless power transmission board 220 may each be formed in a loop shape by winding a conductive wire multiple times around a winding axis.

Here, the plurality of transmission coils 222 may be arranged on a sheet made of a magnetic material such as ferrite, at positions spaced apart from each other by a predetermined distance. The distance between the transmission coils 222 may be less than a width of the reception coils 232, which will be described later.

Furthermore, the plurality of transmission coils 222 may be formed in a multi-layer stacked structure. In other words, a structure formed by stacking a plurality of first transmission coils 222a and a plurality of second transmission coils 222b may be formed on one surface of the wireless power transmission board 220 facing the wireless power reception board 230.

In this case, the plurality of first transmission coils 222a may be arranged parallel to each other on one surface of the magnetic sheet to form a first transmission layer TL1. Each of the plurality of first transmission coils 222a may be arranged to be spaced apart from adjacent first transmission coils 222a by a predetermined distance so as not to overlap each other on the surface of the magnetic sheet.

The plurality of second transmission coils 222b may be disposed above the first transmission layer TL1, thus forming a second transmission layer TL2. The plurality of second transmission coils 222b may be arranged above the first transmission layer TL1 in a structure in which each second transmission coil 222b is spaced apart by a predetermined distance from adjacent second transmission coils 222b so as not to overlap each other.

As such, the wireless power supply unit has a multi-layer stacked structure in which the plurality of transmission coils 222 are stacked, and the first transmission coils 222a and the second transmission coils 222b are alternately arranged, thereby minimizing sections where wireless power transmission efficiency is reduced during movement of the vehicle seat 100.

As illustrated in FIG. 7, the wireless power transmission board 220 may include an inverter circuit 222c, a boost DC/DC converter circuit 222d, and an electromagnetic interference (EMI) filter circuit 222e, which are connected to each of the transmission coils 222. The inverter circuit 222c may include a gate driver and a full bridge circuit.

The wireless power reception board 230 may include a rectifier circuit 232a and a buck DC/DC converter circuit 232b. The rectifier circuit 232a may be configured with a plurality of diodes.

The wireless power reception board 230 as described above may supply rectified and converted power to internal devices of the vehicle seat 100, that is, various loads 232c, through the rectifier circuit 232a and the buck DC/DC converter circuit 232b.

The wireless power supply unit configured as described above can simplify the circuit configuration for wireless power transmission by minimizing the number of installed transmission coils 222 and thereby minimizing the number of inverter circuits 222c, which have relatively complex configurations.

Even if the number of reception coils 232 increases, and accordingly, the number of rectifier circuits 232a increases, the rectifier circuits 232a can be implemented with a relatively simple circuit configuration compared to the inverter circuits 222c, since the rectifier circuits 232a are configured with only diodes, whereas each inverter circuit 222c is configured with a gate driver and a full bridge circuit. Therefore, the circuit configuration of the wireless power supply unit can be further simplified, thereby providing an additional effect of minimizing the manufacturing cost and weight of the wireless power supply unit.

The wireless power supply unit installed inside the rail frame 200 may generate a large amount of electromagnetic waves during wireless power transmission from the wireless power transmission board 220 to the wireless power reception board 230.

The electromagnetic waves generated during wireless power transmission and reception may be emitted to the outside through the region of the first opening 202, which is an open space formed in the upper surface of the rail frame 200, thereby causing damage to or malfunction of various electronic components installed in the vehicle.

In the present disclosure, a shielding component having an electromagnetic wave shielding function is provided in the space of the first opening 202 to maximally suppress electromagnetic waves generated during the operation of the wireless power supply unit from being emitted to the outside through a gap space of the first opening 202 and causing damage to or malfunction of various electronic components mounted in the vehicle.

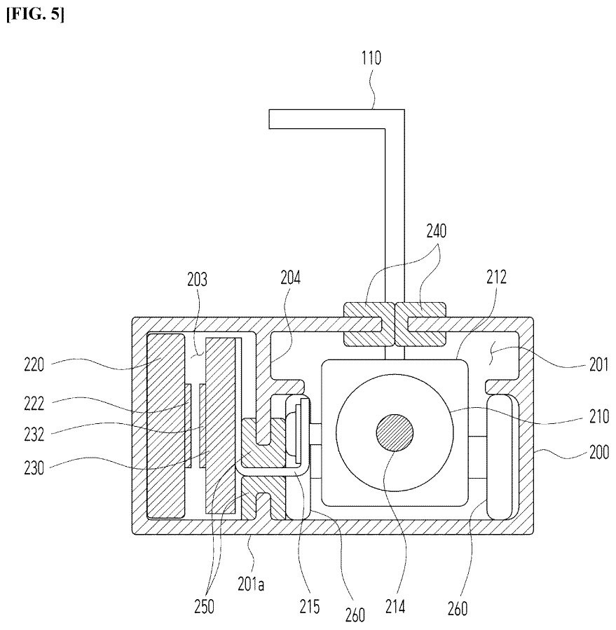

Specifically, as illustrated in FIG. 5, the first shielding component 240 having an electromagnetic wave shielding function is provided at the first opening 202 formed in the upper surface of the rail frame 200, the first opening 202 allowing movement of the seat connector 110, so as to prevent electromagnetic waves generated during wireless power transmission from the wireless power transmission board 220 to the wireless power reception board 230 from being emitted to the outside through the first opening 202.

In this case, a shielding component having various shapes and coupling structures, which allow linear movement of the seat connector 110 along the first opening 202 and are capable of effectively shielding the open space of the first opening 202, may be used as the first shielding component 240.

For example, the first shielding component 240 may be formed by mixing an elastically deformable material with EMI powder having an electromagnetic wave shielding function.

In this case, the first shielding component 240 may have a form that is elastically deformable upon contact with the seat connector 110 when the seat connector 110 moves along the first opening 202, and returns to its original state when the contact with the seat connector 110 is released.

As one example, as shown in the embodiment of FIG. 5, the first shielding component 240 may be configured in the form of sponge or memory foam having a certain thickness with an electromagnetic wave shielding function and elastic restoring force.

In addition, such a pair of first shielding components 240 may be installed to face each other on opposite sides of the first opening 202, so that respective ends of the opposite first shielding components 240 elastically come into contact with each other to close the first opening 202.

In this case, the first shielding components 240 may be installed in a form enclosing upper and lower surfaces of a portion of the rail frame 200 around the first opening 202, as shown in the embodiment of FIG. 5.

Alternatively, the first shielding components 240 may be installed on only one of the upper surface or the lower surface of the portion of the rail frame 200 around the first opening 202.

In this case, it is preferable that a portion of each first shielding component 240 that is directly fixed to the portion of the rail frame 200 around the first opening 202 be formed of a hard material having a relatively high elastic modulus to secure a certain level of fixing force, and a portion of the first shielding component 240 that directly contacts the seat connector 110 be formed of a flexible material such as sponge or memory foam having a relatively low elastic modulus.

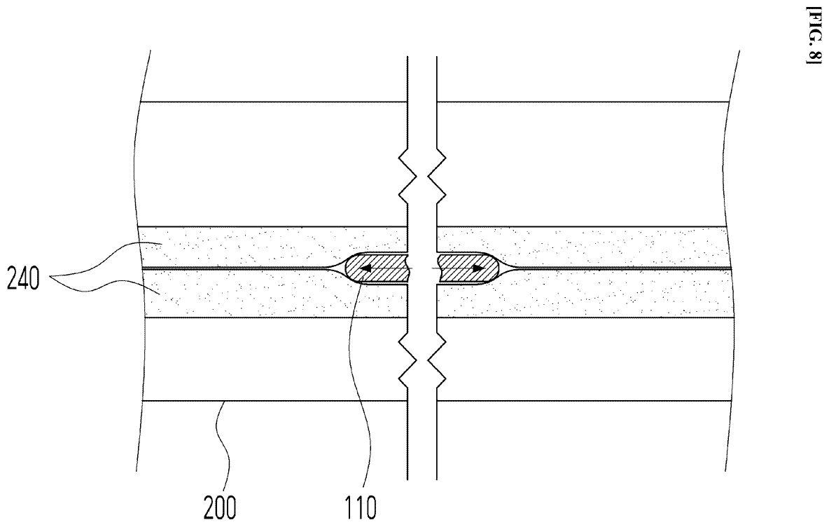

With the foregoing configuration, as illustrated in the plan view of FIG. 8, portions of the pair of first shielding components 240 that are installed on the opposite sides of the first opening 202 and contact the seat connector 110 enclose the periphery of the seat connector 110 and close a region of the first opening 202, and the end of the first shielding components 240 on the opposite sides come into close contact with each other in other regions of the first opening 202 where the seat connector 110 is not positioned, thus completely closing the first opening 202.

Therefore, the first shielding components 240, which close the entire region of the first opening 202, may almost completely prevent electromagnetic waves generated inside the rail frame 200 during the operation of the wireless power supply unit from being emitted to the outside of the rail frame 200, thereby minimizing emission of electromagnetic waves to the outside of the rail frame 200.

Furthermore, during movement of the seat connector 110 along the first opening 202 by the operation of the motor 210, the seat connector 110 may easily squeeze between the respective ends of the first shielding components 240 installed on the opposite sides of the first opening 202, and may smoothly move in the first opening 202, thereby causing no interference with smooth operation of the vehicle seat 100.

In addition, the first shielding components 240 close most of the space of the first opening 202, thereby effectively preventing foreign substances from entering the inside of the rail frame 200 through the space of the first opening 202.

Here, in order to minimize friction between the seat connector 110 and the opposite first shielding components 240 during linear movement of the seat connector 110, a separate coating layer for reducing a friction coefficient may be formed on an outer surface of the seat connector 110 or the first shielding components 240.

As illustrated in FIG. 5, the second shielding component 250 having the same electromagnetic wave shielding function as the first shielding component 240 may also be provided at the second opening 205 located in the internal partition wall 204 of the rail frame 200.

The second shielding component 250 may prevent electromagnetic waves, which are generated during wireless power transmission from the transmission coils 222 of the wireless power transmission board 220 to the reception coils 232 of the wireless power reception board 230, from being emitted into the first space 201 through the space of the second opening 205.

In this case, various types of shielding components, which allow linear movement of the connection bracket 215 along the space of the second opening 205 and are capable of effectively blocking electromagnetic waves emitted through a gap space of the second opening 205, may be used as the second shielding component 250.

The second shielding component 250 may be formed, in the same manner as the above-described first shielding component 240, by mixing an elastically deformable material with EMI powder having an electromagnetic wave shielding function.

Here, the second shielding component 250 may be formed of various materials capable of undergoing elastic deformation while coming into contact with the connection bracket 215 during movement of the connection bracket 215 along the second opening 205, and capable of elastically returning to its original state when the contact with the connection bracket 215 is released.

For example, the second shielding component 250 may be configured, in the same manner as the first shielding component 240, in the form of sponge or memory foam with an electromagnetic wave shielding function and elastic restoring force. In addition, such a pair of second shielding components 250 may be installed to face each other on opposite upper and lower sides of the second opening 205, so that respective ends of the opposite second shielding components 250 elastically come into contact with each other to close the second opening 205.

As illustrated in the embodiment of FIG. 5, the second shielding component 250 may be installed in a form enclosing left and right side surfaces of the partition wall 204 where the second opening 205 is located, or may be installed in a form fixed to only one of the left side surface or the right side surface of the partition wall 204.

Here, in order to minimize friction between the connection bracket 215 and the opposite second shielding components 250 during linear movement of the connection bracket 215, a separate coating layer for reducing a friction coefficient may be formed on an outer surface of the connection bracket 215 or the second shielding components 250.

The second shielding components 250 allow movement of the connection bracket 215 along the second opening 205 and can close a gap space of the second opening 205, thereby maximally suppressing electromagnetic waves generated during wireless power transmission and reception from being emitted into the first space 201 through the space of the second opening 205.

As described above, the present disclosure is configured such that during the operation of the wireless power supply unit, the second shielding components 250 primarily prevent electromagnetic waves from being emitted through a gap space of the second opening 205, and the first shielding components 240 secondarily prevent electromagnetic waves from being emitted through a gap space of the first opening 202, thereby significantly reducing electromagnetic waves emitted to the outside of the rail frame 200. Accordingly, the present disclosure can minimize electromagnetic waves generated from the vehicle seat 100, thereby markedly contributing to securing stringent EMI certification for vehicle electronic components.

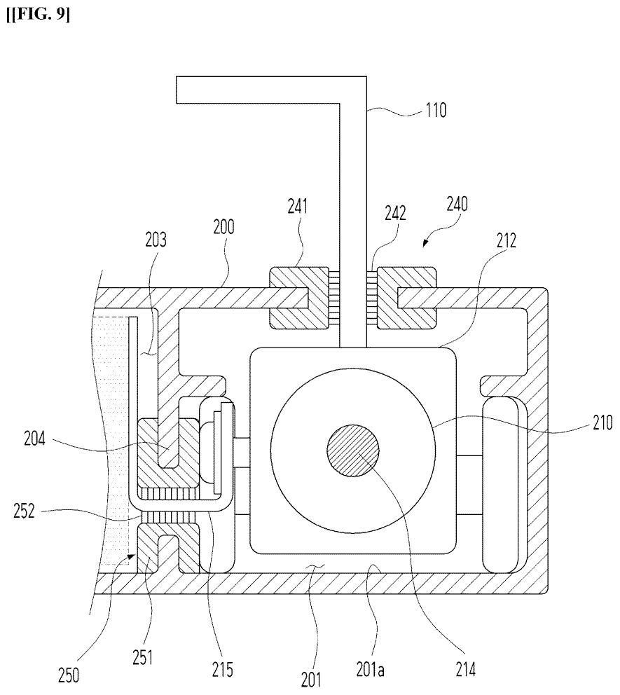

FIG. 9 is another embodiment of the present disclosure, illustrating an example in which a shielding component having a brush structure is applied.

As illustrated in FIG. 9, first and second shielding components 240 and 250 according to an embodiment of the present disclosure may be configured in the form of brushes having an electromagnetic wave shielding function and elastic restoring force.

In this case, the first shielding component 240 may include a coupling portion 241 that is directly fixed to the portion of the rail frame 200 around the first opening 202 and is formed of a hard material having a relatively high elastic modulus to secure a certain level of fixing force, and an elastic portion 242 that directly contacts the seat connector 110 and is formed of a flexible brush structure having a relatively low elastic modulus.

In addition, such a pair of first shielding components 240 may be installed to face each other on opposite sides of the first opening 202, so that the brush-shaped elastic portions 242 located at opposite ends of the first shielding components 240 come into close contact with each other, thereby closing the first opening 202.

The second shielding component 250 may also include a coupling portion 251 that is directly fixed to the portion of the partition wall 204 around the second opening 205 and is formed of a hard material having a relatively high elastic modulus, and an elastic portion 252 that directly contacts the connection bracket 215 and is formed in a flexible brush shape having a relatively low elastic modulus.

Furthermore, such a pair of second shielding components 250 may be installed to face each other on opposite sides of the second opening 205, so that the brush-shaped elastic portions 252 located at opposite ends of the second shielding components 250 come into close contact with each other, thereby closing the second opening 205.

As described above, in the case where the first and second shielding components 240 and 250 are implemented in a brush structure, the first and second shielding components 240 and 250 can respectively close the gap spaces of the first opening 202 and the second opening 205, without affecting smooth movement of the seat connector 110 along the first opening 202 or the connection bracket 215 along the second opening 205, thereby blocking electromagnetic wave from being emitted. Accordingly, the amount of electromagnetic waves emitted to the outside of the rail frame 200 can be minimized.

In addition, the first shielding components 240 formed in a brush structure close most of the space of the first opening 202, thereby preventing foreign substances from entering the inside of the rail frame 200 through the space of the first opening 202.

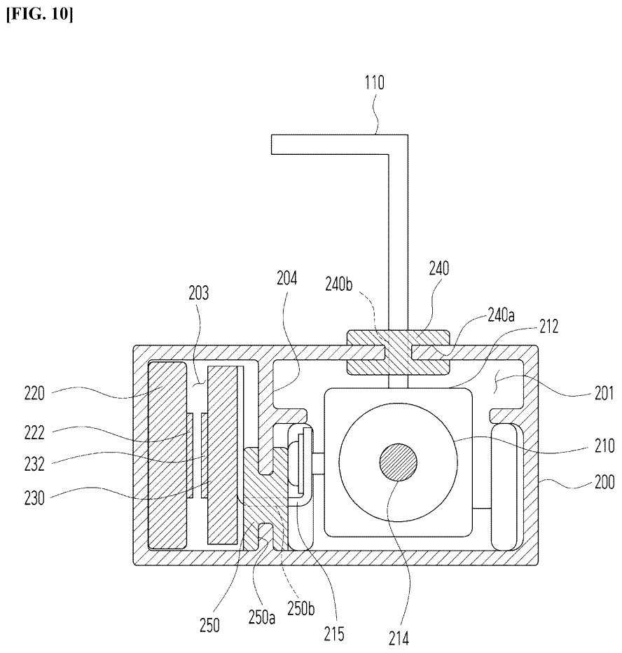

FIG. 10 illustrates another type of shielding component structure that can be installed at the first opening 202 and the second opening 205 of the rail frame 200.

In FIG. 10, the first and second shielding components 240 and 250, which are installed at the first and second openings 202 and 205, may be implemented with flat bar-shaped shielding components 240 and 250 made of rubber or plastic material having an electromagnetic wave shielding function.

In this case, coupling grooves 240a and 250a each having a U-shaped recessed shape may be formed in opposite side portions of the shielding components 240 and 250, which are coupled to the openings 202 and 205, respectively, so that portions defining the coupling grooves 240a and 250a formed in the opposite side portions of the shielding components 240 and 250 can be respectively force-fitted over the portions around the openings 202 and 205.

That is, the shielding components 240 and 250 can be coupled to the respective openings 202 and 205 by pushing and fitting the portions defining the coupling grooves 240a and 250a of the shielding components 240 and 250 onto the portions defining the openings 202 and 205 from one end of the rail frame 200.

Furthermore, through-holes 240b and 250b, through which the seat connector 110 and the connection bracket 215 can respectively pass and be coupled to the shielding components 240 and 250, may be formed in central portions of the shielding components 240 and 250 in a longitudinal direction.

Accordingly, during movement of the seat connector 110 and the connection bracket 215, the shielding components 240 and 250 can slide along the openings 202 and 205 while moving together with the seat connector 110 and the connection bracket 215, respectively.

In this case, to reduce friction generated during sliding movement of the shielding components 240 and 250 along the openings 202 and 205, a lubricant may be applied to each of the portions defining the coupling grooves 240a and 250a of the respective shielding components 240 and 250, or to each of the portions defining the openings 202 and 205 that come into contact with the portions defining the coupling grooves 240a and 250a.

Alternatively, a thin coating layer made of a material having a low friction coefficient may be formed on each of the portions defining the coupling grooves 240a and 250a of the shielding components 240 and 250, or on each of the portions defining the openings 202 and 205, thereby minimizing friction generated upon contact with the portions defining the openings 202 and 205 during sliding movement of the shielding components 240 and 250.

The bar-shaped shielding components 240 and 250 configured as described above can respectively slide, during movement of the seat connector 110 and the connection bracket 215, along the openings 202 and 205 in conjunction with the seat connector 110 and the connection bracket 215, and can partially close the spaces of the respective openings 202 and 205, thereby blocking some of electromagnetic waves emitted through the spaces of the openings 202 and 205, respectively.

Here, the overall lengths of the shielding components 240 and 250 may be formed such that the seat connector 110 and the connection bracket 215 can move within predetermined ranges along the length sections of the respective openings 202 and 205, and such that the spaces of the respective openings 202 and 205 can be maximally shielded by the shielding components 240 and 250.

In this case, because the shielding components 240 and 250 are installed in such a way as to slide along the openings 202 and 205, electromagnetic waves may be emitted to the outside to some extent in some sections of the openings 202 and 205 that are not covered by the shielding components 240 and 250 during the movement of the shielding components 240 and 250.

However, since the shielding components 240 and 250 shield most of the spaces of the openings 202 and 205, the amount of electromagnetic waves emitted to the outside through uncovered sections of the openings 202 and 205 is negligible, and thus does not cause any malfunction of electronic components mounted in the vehicle.

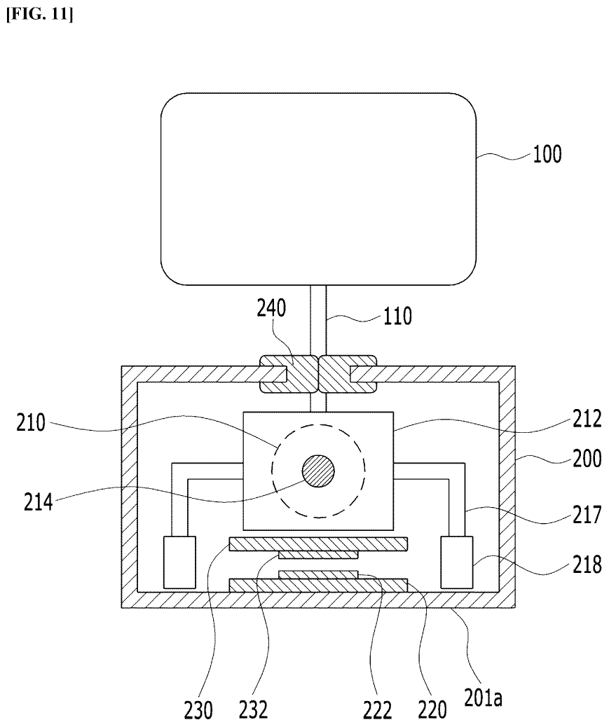

FIG. 11 illustrates an internal configuration and an electromagnetic wave shielding structure of a rail frame 200 according to another embodiment of the present disclosure.

A wireless power supply device for a vehicle seat according to the embodiment shown in FIG. 11 is driven in such a way that the vehicle seat 100 moves in a forward or backward direction along the single rail frame 200 installed below the vehicle seat 100.

In the vehicle seat 100 having the aforementioned driving method, an opening 202, similar to the embodiment shown in FIG. 5, is formed in an upper surface of the rail frame 200 to allow linear movement of a seat connector 110 connected to the vehicle seat 100, and a motor 210 coupled to a lower end of the seat connector 110 is installed in an internal space of the rail frame 200 to be movable linearly along the rail frame 200.

In addition, a wireless power transmission board 220 provided with a plurality of transmission coils 222 connected to the power source inside the vehicle to wirelessly transmit power is fixed to one side inside the rail frame 200, and a wireless power reception board 230 provided with a plurality of reception coils 232 configured to receive power wirelessly transmitted from the transmission coils 222 is installed at a position facing the wireless power transmission board 220 so as to be movable linearly inside the rail frame 200 in conjunction with the motor 210.

Furthermore, a shielding component 240 is installed at the opening 202 formed in an upper portion of the rail frame 200 to block electromagnetic waves generated during wireless power transmission from the wireless power transmission board 220 to the wireless power reception board 230 from being emitted to the outside through the opening 202.

In this case, a shielding component formed by mixing an elastically deformable material with EMI powder having an electromagnetic wave shielding function, similar to the type of the shielding component described in the embodiment shown in FIG. 5, may be applied as the shielding component 240.

Preferably, a pair of shielding components 240, each configured in the form of sponge or memory foam having elastic restoring force and provided with an electromagnetic wave shielding function, may be installed on opposite sides of the opening 202 to face each other, such that respective ends thereof elastically come into close contact with each other, thereby closing the opening 202.

Alternatively, as in the embodiment shown in FIG. 9, the shielding components 240 may have respective opposite ends, which come into contact with the seat connector 110 and are configured in the form of a brush with elastic restoring force, so that the pair of shielding components 240 installed on the opposite sides of the opening 202 facing each other can close the opening 202 through the brush structures on opposite sides.

The wireless power transmission board 220 and the wireless power reception board 230 may be installed below the motor 210 at positions spaced apart by predetermined distances from the motor 210, so as to be parallel to a bottom surface 201a of the rail frame 200.

In addition, wheels 218 configured to roll along the rail frame 200 may be provided at lower left and right sides of the motor 210. Here, the wheels 218 may be rotatably coupled to respective lower ends of support frames 217, each having an L-shaped bent shape and coupled to a different one of the opposite side surfaces of the motor 210, so as to roll along the inner bottom surface 201a of the rail frame 200, thereby supporting movement of the motor 210.

In other words, during linear movement of the motor 210 along the lead screw 214, the wheels 218 on opposite sides roll along the inner bottom surface 201a of the rail frame 200 and support the motor 210 from left and right sides. Hence, the motor 210 can stably perform only linear movement along the lead screw 214 without undergoing rotational movement about a movement axis.

In this case, the motor 210 moves linearly along the lead screw 214, with a predetermined height spacing the motor 210 from the bottom surface 201a of the rail frame 200 due to the heights of the L-shaped bent supports 217 and the wheels 218. Therefore, a sufficient clearance space to install the wireless power supply unit including the wireless power transmission board 220 and the wireless power reception board 230 therein can be secured between the motor 210 and the bottom surface 201a of the rail frame 200.

Accordingly, as illustrated in FIG. 11, the wireless power transmission board 220 and the wireless power reception board 230 can be installed in the clearance space formed between the inner sides of the wheels 218 at a position below the motor 210, so as to be parallel to the bottom surface 201a of the rail frame 200.

As described above, since the wireless power transmission board 220 and the wireless power reception board 230 can be installed by utilizing the clearance space formed between the inner sides of the opposite wheels 218 at a position below the motor 210, there is no need to secure additional space for installation of the wireless power transmission and reception boards 220 and 230 inside the rail frame 200. Accordingly, because a horizontal width and a vertical width of the cross-section of the rail frame 200 can be minimized, there is an advantage in that the spatial utilization of the lower portion of the vehicle body where the rail frame 200 is installed can be increased, thereby improving design flexibility for the lower portion of the vehicle body.

Although various embodiments of the present disclosure have been described, the scope of the present disclosure is not limited thereto, and those skilled in the art will appreciate that various modifications are possible, without departing from the scope of the present disclosure as disclosed in the accompanying claims.

1. A wireless power supply device for a vehicle seat, comprising:
a pair of rail frames each having a first opening formed to allow linear movement of a seat connector connected to the vehicle seat;
a motor coupled to the seat connector and linearly movably installed inside each of the pair of rail frames;
a wireless power transmission board fixed inside the rail frame, and provided with a plurality of transmission coils connected to a power source inside a vehicle to wirelessly transmit power; and
a wireless power reception board disposed at a position facing the wireless power transmission board, and provided with a reception coil configured to receive power wirelessly transmitted from the transmission coils, the wireless power reception board being configured to move linearly in conjunction with the motor,
wherein the wireless power transmission board and the wireless power reception board are installed perpendicular to a bottom surface of the rail frame at positions spaced apart in a horizontal direction from the motor.

2. The wireless power supply device of claim 1, wherein a first shielding component is installed at the first opening of the rail frame and configured to block electromagnetic waves generated during wireless power transmission from the wireless power transmission board to the wireless power reception board from being emitted outside through the first opening.

3. The wireless power supply device of claim 2, wherein the first shielding component is formed by mixing an elastically deformable material with electromagnetic interference (EMI) powder having an electromagnetic wave shielding function.

4. The wireless power supply device of claim 3, wherein the first shielding component is formed of memory foam having elastic restoring force, and comprises a pair of first shielding components installed on opposite sides facing each other in the first opening and configured to close the first opening by elastically coming into close contact with each other.

5. The wireless power supply device of claim 3, wherein the first shielding component is formed in a brush structure having elastic restoring force, and comprises a pair of first shielding components installed on opposite sides facing each other in the first opening and configured to close the first opening.

6. The wireless power supply device of claim 1, wherein the rail frame includes
a first space in which the motor is disposed, and
a second space partitioned from the first space by a partition wall, with the wireless power transmission board and the wireless power reception board disposed in the second space.

7. The wireless power supply device of claim 6, wherein the wireless power transmission board and the wireless power reception board are installed in the second space and oriented perpendicular to the bottom surface of the rail frame.

8. The wireless power supply device of claim 6, wherein a second opening is formed in the partition wall to allow linear movement of a connection bracket that connects the wireless power reception board to the motor.

9. The wireless power supply device of claim 8, wherein a second shielding component is installed at the second opening and configured to block electromagnetic waves generated during wireless power transmission from the wireless power transmission board to the wireless power reception board from being emitted to the first space through the second opening.

10. The wireless power supply device of claim 9, wherein the second shielding component is formed by mixing an elastically deformable material with electromagnetic interference (EMI) powder having an electromagnetic wave shielding function.

11. The wireless power supply device of claim 10, wherein the second shielding component is formed of memory foam having elastic restoring force, and comprises a pair of second shielding components installed on opposite sides facing each other in the second opening and configured to close the second opening by elastically coming into close contact with each other.

12. The wireless power supply device of claim 10, wherein the second shielding component is formed in a brush structure having elastic restoring force, and comprises a pair of second shielding components installed on opposite sides facing each other in the second opening and configured to close the second opening.

13. A wireless power supply device for a vehicle seat, comprising:
a rail frame having an opening formed to allow linear movement of a seat connector connected to the vehicle seat;
a motor coupled to the seat connector and linearly movably installed inside the rail frame;
a wireless power transmission board fixed to one side inside the rail frame, and provided with a plurality of transmission coils connected to a power source inside a vehicle to wirelessly transmit power; and
a wireless power reception board provided with a plurality of reception coils configured to receive power wirelessly transmitted from the transmission coils, the wireless power reception board being disposed at a position facing the wireless power transmission board and configured to move linearly in conjunction with the motor,
wherein the wireless power transmission board and the wireless power reception board are installed below the motor at positions spaced apart from the motor, and are oriented parallel to a bottom surface of the rail frame.

14. The wireless power supply device of claim 13, further comprising wheels disposed on opposite sides below the motor and configured to roll along the rail frame,
wherein the wireless power transmission board and the wireless power reception board are installed in an inner space between the opposite wheels positioned below the motor, and are oriented parallel to a bottom surface of the rail frame.

15. The wireless power supply device of claim 13, wherein a shielding component is installed at the opening of the rail frame and configured to block electromagnetic waves generated during wireless power transmission from the wireless power transmission board to the wireless power reception board from being emitted outside through the opening.

16. The wireless power supply device of claim 15, wherein the shielding component is formed by mixing an elastically deformable material with electromagnetic interference (EMI) powder having an electromagnetic wave shielding function.

17. The wireless power supply device of claim 16, wherein the shielding component is formed of memory foam having elastic restoring force, and comprises a pair of shielding components installed on opposite sides facing each other in the opening and configured to close the opening by elastically coming into close contact with each other.

18. The wireless power supply device of claim 16, wherein the first shielding component is formed in a brush structure having elastic restoring force, and comprises a pair of shielding components installed on opposite sides facing each other in the opening and configured to close the opening.
